(19) United States
(12) Patent Application Publication
(10) Pub. No.: US 2005/0030719 A1
(43) Pub. Date: Feb. 10, 2005

(54) Heat dissipating device for dissipating heat generated by an electronic component inside a housing

(75) Inventors: Ming-Tarn Lin, Chiayi Hsien (TW); Yung-Hsiang Lin, Taipei Hsien (TW); Chung-Ter Yang, Hsinchu (TW)

Correspondence Address: OSTROLENK FABER GERB & SOFFEN, 1180 AVENUE OF THE AMERICAS, NEW YORK, NY, 100368403, US

(73) Assignee: Wincomm Corporation

(21) Appl. No.: 10/719,340

(22) Filed: Nov. 21, 2003

(30) Foreign Application Priority Data
Aug. 7, 2003 (TW) 092121684

(51) Int. Cl. H05K 7/20

(52) U.S. Cl. 361/719

(57) ABSTRACT

In a heat dissipating device, a heat-conducting unit is disposed in a housing and has a first heat-conducting member mounted on a circuit board inside the housing and contacting and in thermal communication with an electronic component mounted on the circuit board, and a second heat-conducting member that has a first end portion connected to the first heat-conducting member, and a second end portion opposite to the first end portion and extending outwardly of the housing through a through hole in the housing. A heat-dissipating fin module is mounted externally of the housing, and has a base plate connected to and in thermal communication with the second end portion of the second heat-conducting member, and a plurality of fin posts mounted fixedly and spacedly on and in thermal communication with the base plate.

### CROSS-REFERENCE TO RELATED APPLICATION

This application claims priority of Taiwanese Application No. 092121684, filed on Aug. 7, 2003.

### BACKGROUND OF THE INVENTION

1. Field of the Invention

The invention relates to a heat dissipating device, more particularly to a heat dissipating device for dissipating heat generated by an electronic component in a housing of an electronic apparatus.

2. Description of the Related Art

FIG. 1 illustrates a computer apparatus with a conventional heat dissipating device 10 for dissipating heat generated by a central processing unit 1 mounted on a circuit board inside a housing 12. The conventional heat dissipating device 10 includes a base plate mounted on the circuit board and contacting and in thermal communication with the central processing unit 1, and a plurality of fin plates 11 mounted fixedly on and in thermal communication with the base plate. The housing 12 is formed with a plurality of vent holes 13 such that heat accumulated in the fin plates 11 is dissipated outside of the housing 12 solely by air flow through the vent holes 13. In such a configuration, the heat generated by the central processing unit 1 cannot be rapidly dissipated.

FIG. 2 illustrates a computer apparatus with another conventional heat dissipating device 15 for dissipating heat generated by an electronic component inside a housing 16. The conventional heat dissipating device 15 contacts and is in thermal communication with the electronic component and the housing 16. Although heat generated by the electronic component can be conducted to the housing 16 via the conventional heat dissipating device 15 so as to increase the heat-dissipating area, too much heat accumulated in the housing 16 results in an adverse affect on the electronic component.

### SUMMARY OF THE INVENTION

Therefore, the object of the present invention is to provide a heat dissipating device for rapidly and effectively dissipating heat generated by an electronic component in a housing of electronic apparatus.

According to one aspect of the present invention, there is provided a heat dissipating device for dissipating heat generated by an electronic component mounted on a circuit board inside a housing. The housing has opposite first and second walls, one of which is formed with a through hole. The heat dissipating device comprises:
a heat-conducting unit adapted to be disposed in the housing, the heat-conducting unit having a first heat-conducting member adapted to be mounted on the circuit board and adapted to contact and to be in thermal communication with the electronic component, and a second heat-conducting member that has a first end portion connected to the first heat-conducting member, and a second end portion opposite to the first end portion and extending outwardly of the housing through the through hole in said one of the first and second walls; and
a heat-dissipating fin module adapted to be mounted on said one of the first and second walls externally of the housing, the heat-dissipating fin module having a base plate connected to and in thermal communication with the second end portion of the second heat-conducting member of the heat-conducting unit, and a plurality of fin posts mounted fixedly and spacedly on and in thermal communication with the base plate.

According to another aspect of the present invention, an electronic apparatus comprises:
a housing having opposite first and second walls, one of which is formed with a through hole;
a circuit board disposed in the housing and provided with an electronic component thereon; and
a heat dissipating device for dissipating heat generated by the electronic component, the heat dissipating device including
   a heat-conducting unit disposed in the housing, the heat-conducting unit having a first heat-conducting member mounted on the circuit board and contacting and in thermal communication with the electronic component, and a second heat-conducting member that has a first end portion connected to the first heat-conducting member, and a second end portion opposite to the first end portion and extending outwardly of the housing through the through hole in said one of the first and second walls, and
   a heat-dissipating fin module mounted on said one of the first and second walls externally of the housing, the heat-dissipating fin module having a base plate connected to and in thermal communication with the second end portion of the second heat-conducting member of the heat-conducting unit, and a plurality of fin posts mounted fixedly and spacedly on and in thermal communication with the base plate.

### BRIEF DESCRIPTION OF THE DRAWINGS

Other features and advantages of the present invention will be come apparent in the following detailed description of the preferred embodiments with reference to the accompanying drawings, of which:

FIG. 1 is a perspective view showing a computer apparatus with a conventional heat dissipating device;

FIG. 2 is a perspective view showing a computer apparatus with another conventional heat dissipating device;

FIG. 3 is an exploded perspective view showing the first preferred embodiment of a heat dissipating device assembled to a computer apparatus according to the present invention;

FIG. 4 is a schematic side view showing the first preferred embodiment;

FIG. 5 is an exploded perspective view showing the second preferred embodiment of a heat dissipating device assembled to a computer apparatus according to the present invention; and

FIG. 6 is a schematic side view showing the third preferred embodiment of a heat dissipating device assembled to a computer apparatus according to the present invention.

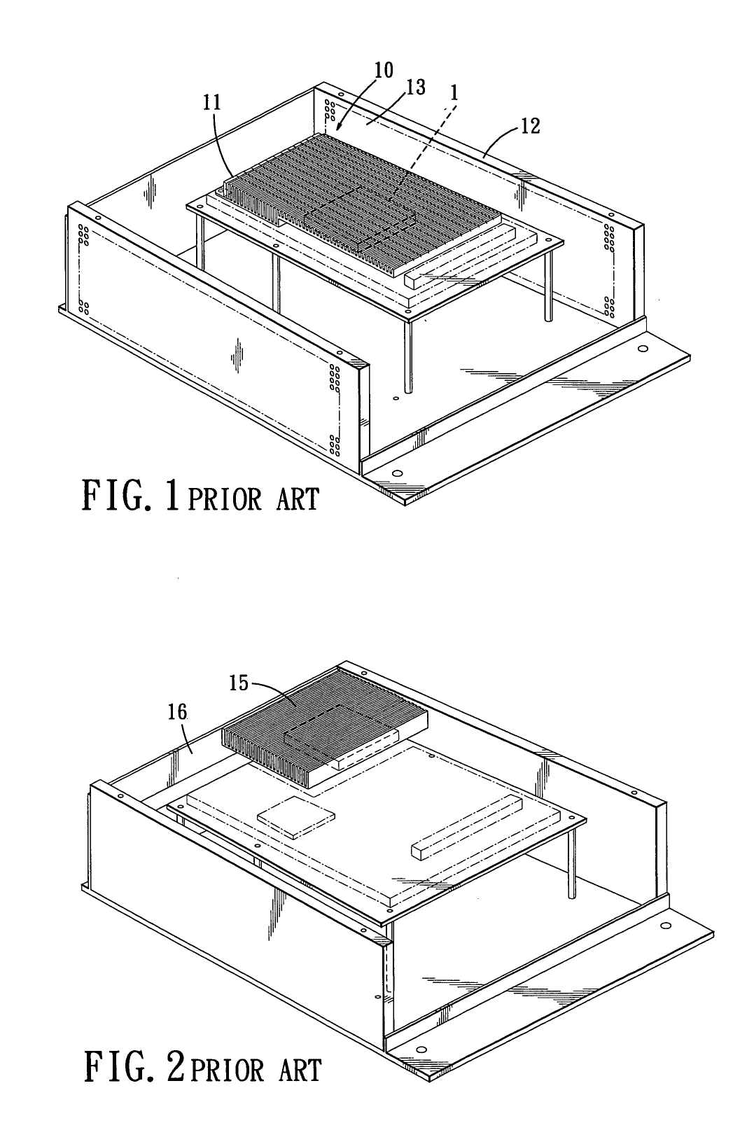

### DETAILED DESCRIPTION OF THE PREFERRED EMBODIMENTS

Before the present invention is described in greater detail, it should be noted that like elements are denoted by the same reference numerals throughout the disclosure.

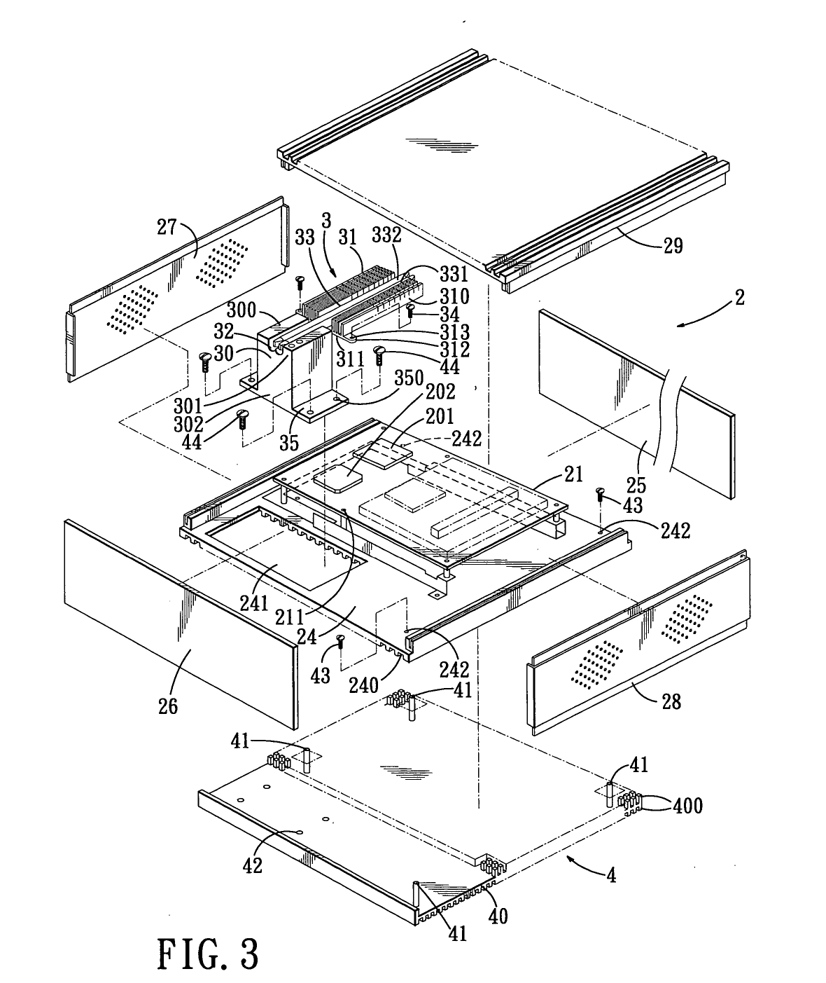

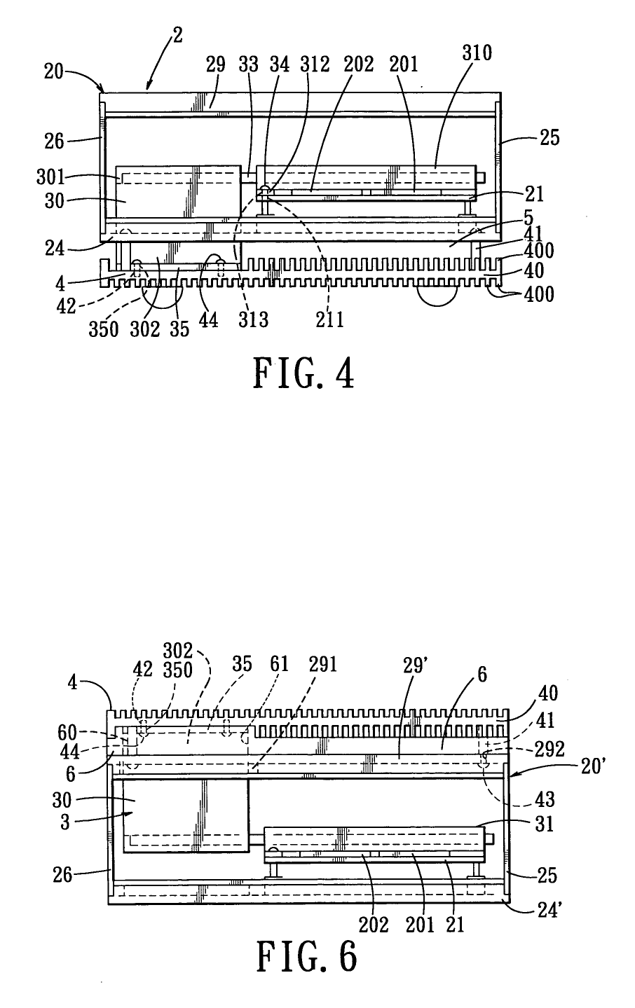

Referring to FIGS. 3 and 4, the first preferred embodiment of a heat dissipating device according to the present invention is shown to be adapted for dissipating heat generated by electronic components 201, 202, such as a central processing unit and a south bridge chip, mounted on a circuit board 21 inside a housing 20 of a computer apparatus 2. In this embodiment, the housing 20 has opposite front and rear walls 26, 25, opposite lateral side walls 27, 28, and opposite top and bottom wall 29, 24. The bottom wall 24 is formed with a through hole 241. The heat dissipating device includes a heat-conducting unit 3 and a heat-dissipating fin module 4.

The heat-conducting unit 3 is adapted to be disposed in the housing 20, and has a first heat-conducting member 31 and a second heat-conducting member 30. The first heat-conducting member 31 is adapted to be mounted on the circuit board 21, and is adapted to contact and to be in thermal communication with the electronic components 201, 202. The second heat-conducting member 30 has a first end portion 301 connected to the first heat-conducting member 31, and a second end portion 302 opposite to the first end portion 301 and extending outwardly of the housing 20 through the through hole 241 in the bottom wall 24. In this embodiment, the first heat-conducting member 31 includes a mounting plate 311 adapted to be mounted on the circuit board 21 and adapted to contact and to be in thermal communication with the electronic components 201, 202, a plurality of heat-dissipating fin plates 310 mounted on the mounting plate 311, and a heat pipe 33 having a first section 331 mounted on the mounting plate 311, and a second section 332 opposite to the first section 331 and extending to the second heat-conducting member 30. The mounting plate 311 has opposite mounting lugs 312, each of which is formed with a through hole 313. A screw fastener 34 extends through the through hole 313 in each mounting lug 312 and is fastened in a fastening hole 211 in the circuit board 21 such that the mounting plate 311 is fixed on the circuit board 21, as best shown in FIG. 4. In this embodiment, the first end portion 301 of the second heat-conducting member 30 has a surface 300 formed with a pipe-receiving groove 32 for receiving the second section 332 of the heat pipe 33. The second end portion 302 of the second heat-conducting member 30 has opposite flanges 35, each of which is formed with a pair of through holes 350.

The heat-dissipating fin module 4 is adapted to be mounted on the bottom wall 24 externally of the housing 20. The heat-dissipating fin module 4 has a base plate 40 connected to and in thermal communication with the second end portion 302 of the second heat-conducting member 30 of the heat-conducting unit 3, and a plurality of fin posts 400 mounted fixedly and spacedly on and in thermal communication with the base plate 40. In this embodiment, the base plate 40 is formed with a plurality of fastening holes 42 that are registered with the through holes 350 in the flanges 35 of the second end portion 302 of the second heat-conducting member 30, respectively, and a plurality of mounting posts 41 extending toward the bottom wall 24 of the housing 20 such that the fin posts 400 are spaced apart from the housing 20 so as to form a heat-dissipating space 5 between the bottom wall 24 and the fin module 4 when the fin module 4 is mounted on the housing 20. A screw fastener 43 extends through a through hole 242 in the bottom wall 23 and is fastened in each mounting post 41, as shown in FIG. 4.

To sum up, heat generated by the electronic components 201, 202 can be conducted rapidly via the heat-conducting unit 3 to the heat-dissipating fin module 4, and is then dissipated by the heat-dissipating fin module 4. Therefore, the heat dissipating device of the present invention can ensure effective heat dissipation.

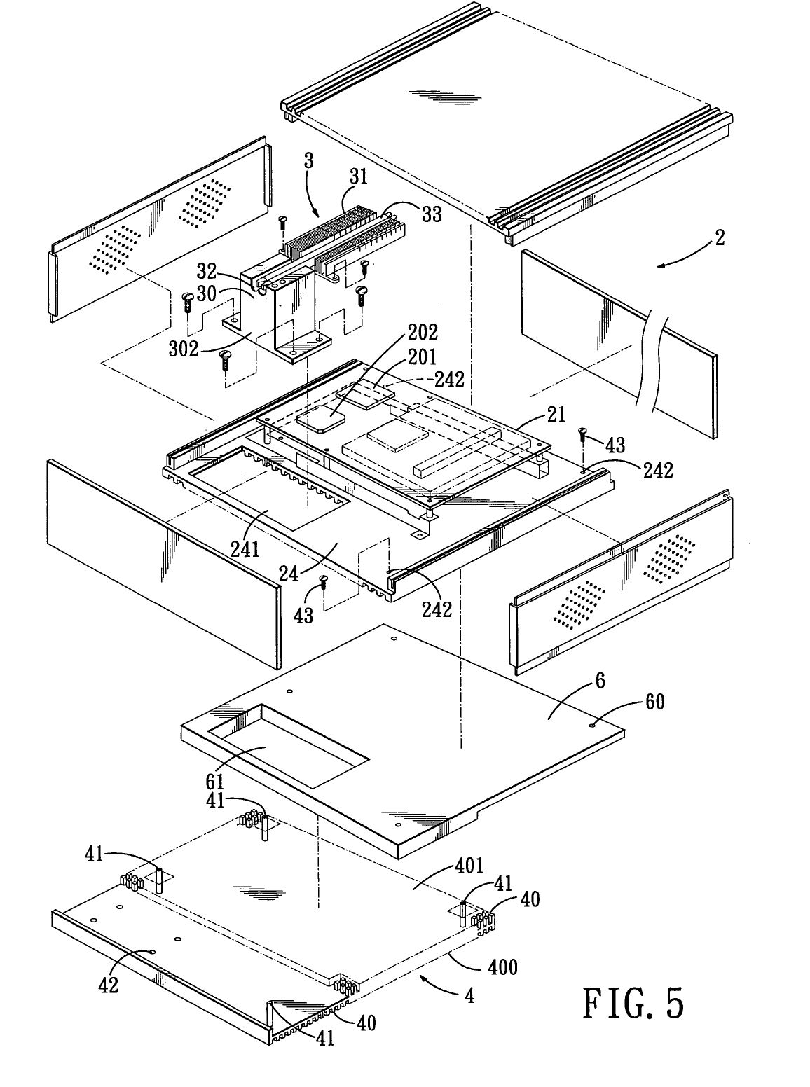

FIG. 5 illustrates the second preferred embodiment of a heat dissipating device for dissipating heat generated by electronic components 201, 202 mounted on a circuit board 21 inside a housing 20 according to this invention, which is a modification of the first preferred embodiment. Unlike the embodiment of FIG. 3, the heat dissipating device further includes a thermal insulating member 6 adapted to be retained between the heat-dissipating fin module 4 and the bottom wall 24 of the housing 20. In this embodiment, the thermal insulating member 62 is a thermal insulating plate that is formed with a mounting hole 61 corresponding to the through hole 241 in the bottom wall 24 of the housing 20 for receiving the second end portion 302 of the second heat-conducting member 30, and a plurality of through holes 60 registered with the mounting posts 41 in the fin module 4, respectively. As such, each screw fastener 43 extends through a corresponding through hole 242 in the bottom wall 24 and a corresponding through hole 60 in the thermal insulating member 6, and is fastened in a corresponding mounting post 41 of the fin module 4.

FIG. 6 illustrates the third preferred embodiment of a heat dissipating device for dissipating heat generated by electronic components 201, 202 mounted on a circuit board 21 inside a housing 20′ according to this invention, which is a modification of the first preferred embodiment. Unlike the embodiment of FIG. 3, the heat-dissipating fin module 4 is adapted to be mounted on the top wall 29′ externally of the housing 20′. In this embodiment, the top wall 29′ is formed with a through hole 291. The second end portion 302 of the second heat-conducting member 30 extends outwardly of the housing 20′ through the through hole 291 in the top wall 29′. The mounting posts 41 on the base plate 40 of the fin module 4 extend toward the top wall 29′. A thermal insulating member 6 is adapted to be retained between the heat-dissipating fin module 4 and the top wall 29 of the housing 20′. A mounting hole 61 in the thermal insulating member 6 is registered with the through hole 291 in the top wall 29′ for receiving the second end portion 302 of the second heat-conducting member 30. Each of a set of screw fasteners 43 extends through a corresponding through hole 292 in the top wall 29′ and a corresponding through hole 60 in the thermal insulating member 6, and is fastened in a corresponding mounting post 41 of the fin module 4.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A heat dissipating device for dissipating heat generated by an electronic component mounted on a circuit board inside a housing, the housing having opposite first and second walls, one of which is formed with a through hole, said heat dissipating device comprising:
a heat-conducting unit adapted to be disposed in the housing, said heat-conducting unit having a first heat-conducting member adapted to be mounted on the circuit board and adapted to contact and to be in thermal communication with the electronic component, and a second heat-conducting member that has a first end portion connected to said first heat-conducting member, and a second end portion opposite to said first end portion and extending outwardly of the housing through the through hole in said one of the first and second walls; and
a heat-dissipating fin module adapted to be mounted on said one of the first and second walls externally of the housing, said heat-dissipating fin module having a base plate connected to and in thermal communication with said second end portion of said second heat-conducting member of said heat-conducting unit, and a plurality of fin posts mounted fixedly and spacedly on and in thermal communication with said base plate.

2. The heat dissipating device as claimed in claim 1, further comprising a thermal insulating member adapted to be retained between said heat-dissipating fin module and said one of the first and second walls of the housing.

3. The heat-dissipating device as claimed in claim 2, wherein said thermal insulating member is a thermal insulating plate that is formed with a mounting hole corresponding to the through hole in said one of the first and second walls of the housing for receiving said second end portion of said second heat-conducting member.

4. The heat dissipating device as claimed in claim 1, wherein said first heat conducting member includes a mounting plate adapted to be mounted on the circuit board and adapted to contact and to be in thermal communication with the electronic component, a plurality of heat-dissipating fin plates mounted on said mounting plate, and a heat pipe having a first section mounted on said mounting plate, and a second section opposite to said first section and extending to said second heat-conducting member.

5. The heat dissipating device as claimed in claim 4, wherein said first end portion of said second heating-conducting member is formed with a pipe-receiving groove for receiving said second section of said heat pipe.

6. The heat dissipating device as claimed claim 1, wherein said base plate of said heat-dissipating fin module is formed with a plurality of mounting posts extending toward said one of the first and second walls of the housing such that said fin posts are spaced apart from the housing when said fin module is mounted on the housing.

7. An electronic apparatus comprising:
a housing having opposite first and second walls, one of which is formed with a through hole;
a circuit board disposed in said housing and provided with an electronic component thereon; and
a heat dissipating device for dissipating heat generated by said electronic component, said heat dissipating device including
a heat-conducting unit disposed in said housing, said heat-conducting unit having a first heat-conducting member mounted on said circuit board and contacting and in thermal communication with said electronic component, and a second heat-conducting member that has a first end portion connected to said first heat-conducting member, and a second end portion opposite to said first end portion and extending outwardly of said housing through said through hole in said one of said first and second walls, and
a heat-dissipating fin module mounted on said one of said first and second walls externally of said housing, said heat-dissipating fin module having a base plate connected to and in thermal communication with said second end portion of said second heat-conducting member of said heat-conducting unit, and a plurality of fin posts mounted fixedly and spacedly on and in thermal communication with said base plate.
